(19) United States
(12) Patent Application Publication
(10) Pub. No.: US 2011/0095677 A1
(43) Pub. Date: Apr. 28, 2011

(54) ORGANIC ELECTROLUMINESCENCE DISPLAY PANEL AND PROCESS FOR PRODUCING THE SAME

(75) Inventors: Tatsuya Yoshizawa, Tsurugashima-Shi (JP); Isamu Ohshita, Tsurugashima-Shi (JP)

(73) Assignee: PIONEER CORPORATION, TOKYO (JP)

(21) Appl. No.: 12/673,215

(22) PCT Filed: Aug. 10, 2007
(86) PCT No.: PCT/JP2007/065733

§ 371 Date: Mar. 22, 2010

(51) Int. Cl. H01J 1/62; H01J 9/24

(52) U.S. Cl. 313/504; 445/24

(57) ABSTRACT

To attain not only reforming of a film moistureproof substrate but also inhibiting of penetration of moisture or water transportation from edge portions thereof. [MEANS FOR SOLVING PROBLEMS] Film moistureproof substrate (7) is fixed to base plane (3a) of frame body (3) with adhesion. The film moistureproof substrate (7) at its edge portions is covered with a moistureproof fixing member, so that when the film moistureproof substrate (7) is fixed to the frame body (3), the thin-film organic electroluminescence element built in the film moistureproof substrate (7) can be freed from influences of moisture and water.

### CROSS-REFERENCE TO RELATED APPLICATION

This is an application PCT/JP2007/065733, filed Aug. 10, 2007, which was not published under PCT article 21(2) in English.

### BACKGROUND OF THE INVENTION

1. Field of the Invention

The present invention relates to an organic electroluminescent display panel comprising a film moistureproof substrate having a built-in organic electroluminescent element, and a manufacturing method thereof.

2. Description of the Related Art

In prior art, EL light-emitting sheets used for a flat-surface backlight have been incapable of forming a light-emitting surface of a curved shaped with the sheet shape as is, requiring a portion of the curved surface to be finished as a flat surface. Accordingly, a thin curved-surface light-emitting panel that uses an EL light-emitting sheet and its manufacturing method employ a method of using a frame to support the end portions of the EL light-emitting sheet to prevent shrinkage on curing in an attempt to correct the EL light-emitting sheet to a predetermined shape (see JP, A, 2000-105557,. According to such a well-known prior art, shape changes such as warping are prevented from occurring on a thin curved-surface light-emitting panel that uses the EL light-emitting sheet, to the extent possible, thereby preventing the occurrence of non-uniform brightness.

### SUMMARY OF THE INVENTION

Nevertheless, while the above-described EL light-emitting sheet is corrected by using the above-mentioned frame to support the end portions and thus form a desired curved surface having elasticity, the possibility exists that humidity, moisture, oxygen, and the like may penetrate from the end portions in a case where space forms between the end portions and the frame.

The above-described problem is given as one example of the problems that are to be solved by the present invention.

### MEANS FOR SOLVING THE PROBLEM

In order to achieve the above-mentioned object, according to the first invention, there is provided an organic electroluminescent display panel, comprising: a frame body on which a desired reference surface is formed; a film moistureproof substrate having a built-in thin-film organic electroluminescent element group; and a moistureproof fixing portion that fixes a front surface of the film moistureproof substrate to the frame body while the front surface of the film moistureproof substrate is in close contact with the reference surface, and covers at least an end portion of the film moistureproof substrate, the moistureproof fixing portion including: an adhesive for fixing the film moistureproof substrate to the frame body while the film moistureproof substrate is in close contact with the reference surface; and a pressing and fixing frame that presses against one surface of the film moistureproof substrate so that the film moistureproof substrate comes in close contact with the reference surface.

In order to achieve the above-mentioned object, according to the seventh invention, there is provided an organic electroluminescent display panel, comprising: a frame body on which a desired reference surface is formed; a film moistureproof substrate having a built-in thin-film organic electroluminescent element group; a moistureproof fixing portion that fixes a front surface of the film moistureproof substrate to the frame body while the front surface of the film moistureproof substrate is in close contact with the reference surface, and covers at least an end portion of the film moistureproof substrate; and another film moistureproof substrate provided along a front surface of the film moistureproof substrate, the frame body including a fixing member body that fixes the other film moistureproof substrate with the film moistureproof substrate superimposed thereon, and the moistureproof fixing portion including a coherence surface of the fixing member body, the coherence surface coming in close contact with a section where there is a difference in surface area of the film moistureproof substrate and the other film moistureproof substrate in a combined state and functioning as the reference surface.

In order to achieve the above-mentioned object, according to the 14th invention, there is provided a manufacturing method of an organic electroluminescent display panel comprising the steps of: a step for fixing a front surface of a film moistureproof substrate having a built-in thin-film organic electroluminescent element group to a frame body in a state that a pressing and fixing frame presses against one surface of said film moistureproof substrate so that said film moistureproof substrate comes in close contact with said reference surface formed on said frame body, while covering at least an end portion of the film moistureproof substrate by using the pressing and fixing frame in a pressing state and an adhesive.

### BRIEF DESCRIPTION OF THE DRAWINGS

FIG. 1 is a perspective view illustrating a configuration example of an organic EL display panel of embodiment 1.

FIG. 2 is an exploded perspective view illustrating a configuration example of the organic EL display panel of FIG. 1, as assembled.

FIG. 3 is a partial cross-sectional view illustrating an example of the film moistureproof substrate fixed to the frame body of FIG. 2.

FIG. 4 is a partial cross-sectional view illustrating an alternative embodiment of the film moistureproof substrate fixed to the frame body of FIG. 3.

FIG. 5 is an exploded perspective view illustrating a configuration example of an organic EL display panel of embodiment 2, as assembled.

FIG. 6 is a partial cross-sectional view illustrating an example of the film moistureproof substrate and the fixing frame fixed to the frame body of FIG. 5.

FIG. 7 is a partial cross-sectional view illustrating an alternative embodiment of the film moistureproof substrate and the fixing frame fixed to the frame body of FIG. 6.

FIG. 8 is a perspective view illustrating a partial process example of assembling the organic EL display panel of embodiment 3.

FIG. 9 is a perspective view illustrating a partial process example of assembling the organic EL display panel of embodiment 3.

FIG. 10 is a perspective view illustrating a partial process example of assembling the organic EL display panel of alternative embodiment 1 of embodiment 3.

FIG. 11 is a perspective view illustrating a partial process example of assembling the organic EL display panel of alternative embodiment 1 of embodiment 3.

FIG. 12 is a cross-sectional view illustrating a first cross-sectional configuration example of the fixing frames of FIG. 10 and FIG. 11.

FIG. 13 is a cross-sectional view illustrating a second cross-sectional configuration example of the fixing frames of FIG. 10 and FIG. 11.

FIG. 14 is a perspective view illustrating an example of fixing the end portions of the film moistureproof substrate using the fixing frames.

FIG. 15 is a perspective view illustrating a partial process example of assembling the organic EL display panel of alternative embodiment 2 of embodiment 3.

FIG. 16 is a cross-sectional view illustrating a configuration example of the fixing frames of FIG. 15.

FIG. 17 is a perspective view illustrating another example of a part of the process of assembling the organic EL display panel.

FIG. 18 is a perspective view illustrating a partial process example of assembling the organic EL display panel of embodiment 4.

FIG. 19 is a perspective view illustrating a partial process example of assembling the organic EL display panel of embodiment 4.

FIG. 20 is a cross-sectional view illustrating a cross-sectional configuration example of the fixing frames of FIG. 19.

FIG. 21 is a perspective view illustrating a partial process example of assembling the organic EL display panel of embodiment 5.

FIG. 22 is a perspective view illustrating a partial process example of assembling the organic EL display panel of embodiment 5.

FIG. 23 is a perspective view illustrating a partial process example of assembling the organic EL display panel of an alternative embodiment of embodiment 5.

FIG. 24 is a perspective view illustrating a partial process example of assembling the organic EL display panel of an alternative embodiment of embodiment 5.

FIG. 25 is a cross-sectional view illustrating a cross-sectional configuration example of the fixing frames of FIG. 23 and FIG. 24.

FIG. 26 is a cross-sectional view illustrating a configuration example of a portion of the organic EL display panel of alternative embodiment 1 of each of the above embodiments.

FIG. 27 is a cross-sectional view illustrating a configuration example of a portion of the organic EL display panel of alternative embodiment 2 of each of the above embodiments.

FIG. 28 is a partial cross-sectional view illustrating an alternative embodiment of the film moistureproof substrate of FIG. 3.

### DETAILED DESCRIPTION OF THE PREFERRED EMBODIMENTS

The following describes embodiments of the present invention with reference to accompanying drawings.

### Embodiment 1

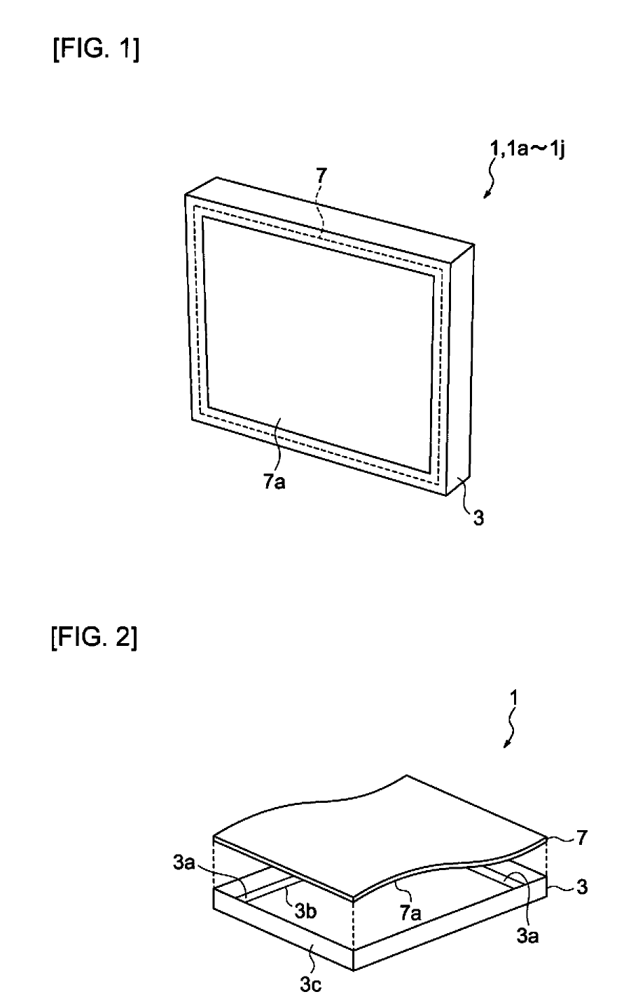

FIG. 1 is a perspective view illustrating a configuration example of an organic electroluminescent display panel 1 of embodiment 1.

The organic electroluminescent display panel 1 in appearance comprises a frame body 3 and a film moistureproof substrate 7. In the following description, “organic electroluminescent display panel” is abbreviated as “organic EL display panel.” This film moistureproof substrate 7 comprises multiple rows of built-in thin-film organic electroluminescent elements, for example. Here, the “thin-film organic electroluminescent elements,” unlike distributed organic electroluminescent elements, form an organic electroluminescent layer via a predetermined film formation process, for example.

The frame body 3 is an external member constituting a housing of the organic EL display panel 1. On the front surface of this frame body 3 is formed an opening, and this opening comprises a display surface 7a of the film moistureproof substrate 7. That is, when the film moistureproof substrate 7 is actuated, light is emitted from the display surface 7a by the action of the distributed organic electroluminescent elements, and a predetermined image is displayed.

FIG. 2 is an exploded perspective view illustrating a configuration example of the organic EL display panel 1 of FIG. 1, as assembled. In this FIG. 2, the organic EL display panel 1 is disassembled with the display surface 7a facing downward as an example, illustrating a simplified view that focuses on the members related to the embodiment. Note that, in FIG. 2, the organic EL display panel 1 may be disassembled with the display surface 7a facing upward.

The organic EL display panel 1 mainly comprises the frame body 3 and the substrate 7. This substrate 7 is a moistureproof substrate that is a film having multiple rows of organic electroluminescent elements as described above and is sealed by a resin such as plastic. In the following description, the substrate 7 is referred to as the “film moistureproof substrate 7.” This film moistureproof substrate 7 has a built-in group of thin-film organic electroluminescent elements.

The frame body 3 is formed into a thin box shape having an opening on the bottom, for example, and the display surface 7a of the film moistureproof substrate 7 is exposed from this opening. That is, the frame body 3 comprises a side portion 3c that forms four surfaces along the thickness direction of organic EL display panel 1, and a frame portion 3b of a predetermined thickness that is formed along the outer edge of the organic EL display panel 1 when viewed from the display surface 7a. A reference surface 3a having a function such as described below is formed on the surface on the backside of the front surface (hereinafter “rear surface”) of the frame portion 3b. This reference surface 3a presses against the film moistureproof substrate 7 when the organic EL display panel 1 is assembled, and is used as a reference for correcting the film moistureproof substrate 7 to a desired shape.

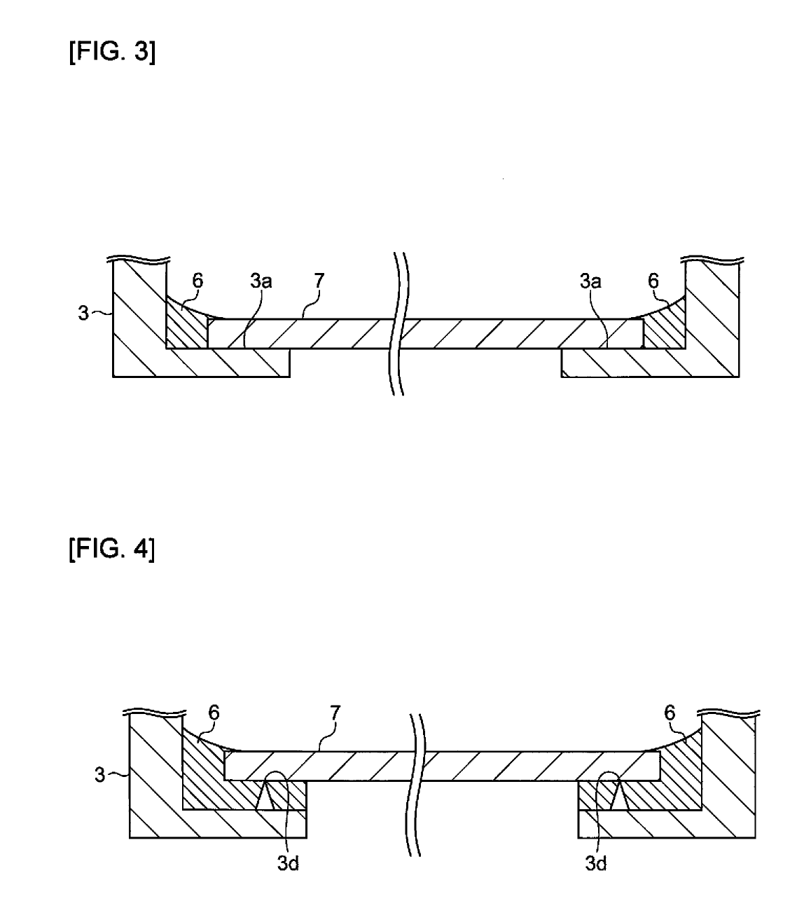

FIG. 3 is a partial cross-sectional view showing an example of the film moistureproof substrate 7 fixed to the frame body 3 of FIG. 2.

This film moistureproof substrate 7 is fixed to the frame body 3 by a moistureproof adhesive 6 (equivalent to a moistureproof fixing portion), with the front surface of the film moistureproof substrate 7 in close contact with the reference surface 3a. This moistureproof adhesive 6 covers the end portions of the film moistureproof substrate 7. The “end portions of the film moistureproof substrate 7” include not only the end surfaces that constitute the thickness of the film moistureproof substrate 7, but also a part of the surrounding front and rear surfaces of the film moistureproof substrate 7.

The moistureproof adhesive 6 is an adhesive for securing the film moistureproof substrate 7 to the frame body 3 with the film moistureproof substrate 7 in close contact with the reference surface, for example. Specifically, the film moistureproof substrate 7 is disposed so that the outer edge portions of the four sides thereof are in close contact with the reference surface 3a provided on the rear surface of the four sides of the frame body 3. The film moistureproof substrate 7 is fixed to the frame body 3 by the moistureproof adhesive 6 at fixing locations of the frame body 3.

The moistureproof adhesive 6 is made of a moistureproof material, and has characteristics such as described later. First, since the distributed electroluminescent element is generally an inorganic material, for example, the required moistureproof function differs from that of the organic electroluminescent element. The moisture permeability of general resin is approximately 1 to 10 [g/m² per day], and the moisture permeability of a resin substrate for an LCD (liquid crystal display) having an added moistureproof barrier film is approximately 0.1 [g/m² per day] or less. Further, the moisture permeability required in a thin-film organic electroluminescent element susceptible to humidity, moisture, and oxygen requires a high moistureproof capability of an even lower numerical value, such as that equivalent to the measurement threshold of the Mocon method, i.e., approximately 0.001 [g/m² per day (g/m² per d)] or less. Note that the moisture permeability (gas barrier characteristics) of a glass substrate is approximately 10⁻³ to 10⁻⁶ (g/m² per day).

According to this embodiment, an acrylic UV curing adhesive is employed as the above-described moistureproof adhesive 6, for example, and the moisture permeability of the end portions of the film moistureproof substrate 7 sealed by this moistureproof adhesive is 10⁻³ [g/m² per day (g/m² per d)] or less, for example. Note that the moistureproof adhesive 6 is not limited to such an acrylic UV curing resin (adhesive), allowing use of resins (adhesives), such as an acrylic or epoxy, that cure by means such as ultraviolet light or heat.

In a case where the moistureproof adhesive 6 employs a joining material such as an epoxy, the joining material is a member through which ultraviolet light passes, for example. A fixing frame 9 described after, etc., is also made of a material that does not block the transmission of ultraviolet light, for example. Examples of material of the fixing frame 9 include plastic and metal. Additionally, in a case where a trim of a size adequate for preventing the penetration of moisture from the end portions of the film moistureproof substrate 7 is employed, the locations covered and fixed by the moistureproof adhesive 6 may be a fraction thereof. Here, the term “trim” refers to the width from the moistureproof substrate end portion to a component member such as the organic functional layer or organic insulating film of the organic EL susceptible to moisture or oxygen.

With this arrangement, the film moistureproof substrate 7 exhibits a correction effect of being corrected to a desired shape that conforms to the reference surface 3a. In addition, since the moistureproof adhesive 6 has moistureproof characteristics as described above, the moistureproof adhesive 6 exhibits a moistureproof effect capable of effectively blocking off the thin-film organic electroluminescent elements susceptible to humidity and moisture from humidity, moisture, and oxygen. In addition, this moistureproof adhesive 6 exhibits an anti-stripping effect capable of preventing a portion thereof from being stripped from the end portions of the film moistureproof substrate 7.

FIG. 4 is a partial cross-sectional view illustrating an alternative embodiment of the film moistureproof substrate 7 fixed to the frame body 3 of FIG. 3.

In FIG. 4, while the frame body 3, the film moistureproof substrate 7, and the adhesive 6 are substantially the same as those shown in FIG. 3, the correction method of the film moistureproof substrate 7 is different. Specifically, a reference point 3d is formed on the rear surface of the frame body 3. Note that this reference point 3d may not only be formed into a point shape, but may also be formed into a linear shape, either partially or fully along the frame portion 3b on the rear surface thereof, for example. In a case that a plurality of reference points 3d are provided, a plane including the plurality of reference points 3d becomes a reference surface that functions equivalent to the reference surface 3a.

An example of the manufacturing method of the organic EL display panel 1 having such a configuration will now be described with reference to FIGS. 1 to 4. According to this manufacturing method, the front surface of the film moistureproof substrate 7 having the built-in thin-film organic electroluminescent element group is fixed to the frame body 3 while in close contact with the reference surface 3a formed on the frame body 3 using the moistureproof fixing portion 6, while covering the end portions of the film moistureproof substrate 7 with the moistureproof fixing portion 6.

The organic EL display panel 1 of the above embodiment comprises the frame body 3 on which the desired reference surface 3a is formed, the film moistureproof substrate 7 having the built-in thin-film organic electroluminescent element group, and the moistureproof fixing portion 6 that fixes the front surface of the film moistureproof substrate 7, which is positioned in close contact with the reference surface 3a, to the frame body 3 and covers at least an end portion of the film moistureproof substrate 7.

In the manufacturing method of the organic EL display panel 1 of the above embodiment, the front surface of the film moistureproof substrate 7 having the built-in thin-film organic electroluminescent element group is fixed to the frame body 3 while in close contact with the reference surface 3a formed on the frame body 3 using the moistureproof fixing portion 6, while covering at least an end portion of the film moistureproof substrate 7 with the moistureproof fixing portion 6.

With this arrangement, since the front surface of the film moistureproof substrate 7 is in close contact with the reference surface 3a of the frame body 3, the film moistureproof substrate 7 is corrected to a shape that conforms with the reference surface 3, even if temporarily deformed. In addition, since the film moistureproof substrate 7 is moistureproof itself and the end portions thereof are covered by the moistureproof fixing portion 6, the film moistureproof substrate 7 is capable of effectively inhibiting the penetration of humidity, moisture, and oxygen from the end portions thereof. Thus, since the film moistureproof substrate 7 is not susceptible to damage by humidity, moisture, or oxygen, even when having built-in thin-film organic electroluminescent elements, it is possible to prevent the formation of so-called dark spots when light is emitted.

In the organic EL display panel 1 of the above embodiment, in addition to the above configuration, the moistureproof fixing portion 6 is the adhesive 6 for fixing the film moistureproof substrate 7 to the frame body 3 while the film moistureproof substrate 7 is in close contact with the reference surface 3a.

With this arrangement, the film moistureproof substrate 7 is not only corrected to a shape as described above, but enables establishment of both a fixing function for fixing itself to the frame body 3 by the adhesive 6 and a moistureproof function of the end portions thereof.

### Embodiment 2

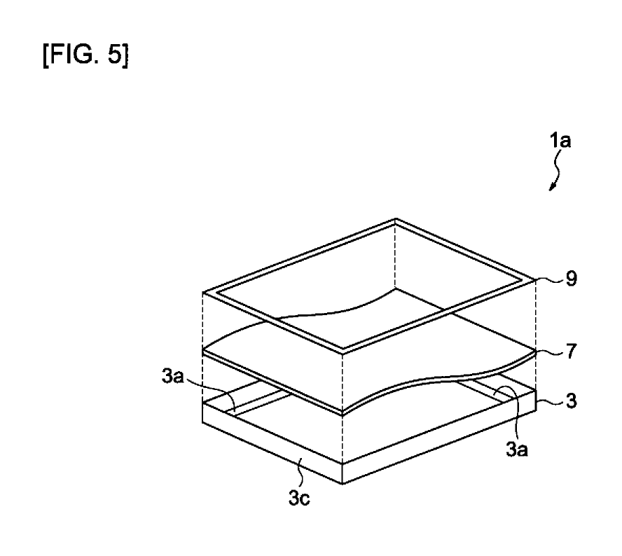

FIG. 5 is an exploded perspective view illustrating a configuration example of an organic EL display panel 1a of embodiment 2, as assembled. In FIG. 5, the organic EL display panel 1 is disassembled with the display surface 7a facing downward, illustrating a simplified view that focuses on the members related to the embodiment.

The organic EL display panel 1a of embodiment 2 has substantially the same configuration and behaves in substantially the same manner as embodiment 1. Thus, the same reference numerals as those in FIGS. 1 to 4 of embodiment 1 denote the same components and behavior, and descriptions thereof will be omitted. The following description will focus on the differences between the embodiments.

While in embodiment 1 the film moistureproof substrate 7 is placed in close contact with the reference surface 3 to correct the film moistureproof substrate 7 to a desired shape, and is fixed to the frame body 3 using the moistureproof adhesive 6, in embodiment 2 the configuration is as follows. That is, according to embodiment 2, the film moistureproof substrate 7 is placed in close contact with a reference surface 3a, the fixing frame 9 is pressed against the film moistureproof substrate 7 from the rear surface thereof to correct the film moistureproof substrate 7 in accordance with the shape of the reference surface 3a and the fixing frame 9, and the film moistureproof substrate 7 and the fixing frame 9 are then fixed to the frame body 3 using the moistureproof adhesive 6. Note that the reference surface 3a may be formed on the fixing frame 9 rather than or in addition to the frame body 3.

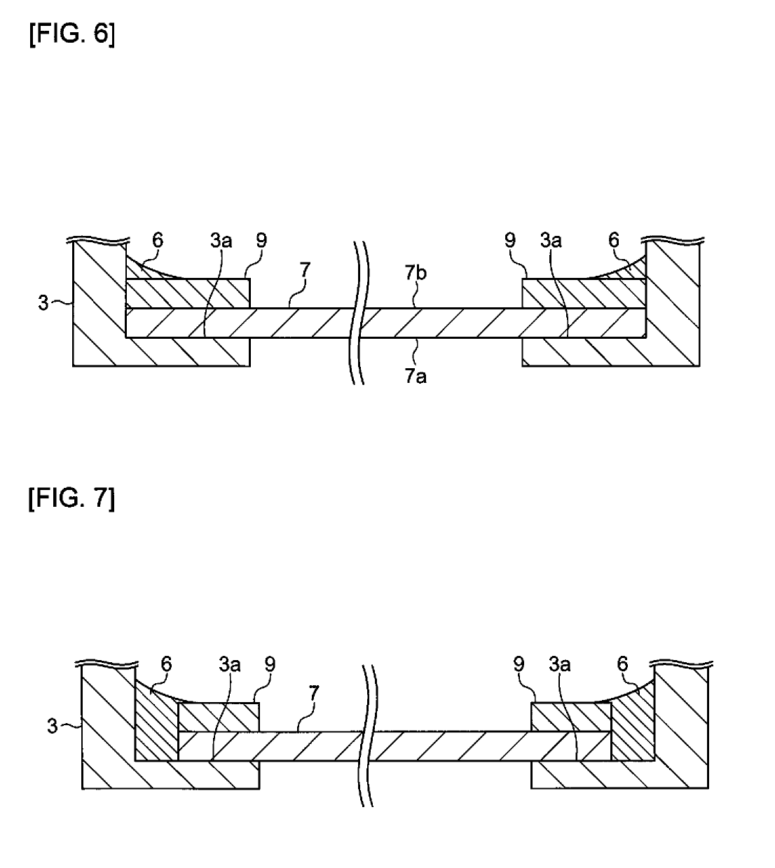

FIG. 6 is a partial cross-sectional view illustrating an example of the film moistureproof substrate 7 and the fixing frame 9 fixed to the frame body 3 of FIG. 5. Since the configuration shown in FIG. 6 is substantially the same as the configuration shown in FIG. 3 of embodiment 1, the following description will focus on the differences therebetween.

The configuration shown in FIG. 6, in addition to the configuration shown in FIG. 3, further comprises the fixing frame 9. This fixing frame 9 is equivalent to a pressing and fixing frame, and is pressed against a rear surface 7b of the film moistureproof substrate 7 so that the film moistureproof substrate 7 comes in close contact with the reference surface 3. This fixing frame 9 is disposed so that the film moistureproof substrate 7 is pressed against the reference surface 3a from one surface (hereinafter represented by the rear surface 7b) of the film moistureproof substrate 7.

The film moistureproof substrate 7 is fixed to the frame body 3 by the moistureproof adhesive 6 with its rear surface 7b pressed against the reference surface 3a by the fixing frame 9. The end surfaces of the film moistureproof substrate 7 and the fixing frame 9 contact the rear surface of the frame body 3 and are fixed to the frame body 3 from the upper surface of the fixing frame 9 by the moistureproof adhesive 6, thereby inhibiting penetration of humidity, moisture, and oxygen from the end portions thereof.

In the organic EL display panel 1a of the above embodiment, the moistureproof fixing portion includes the pressing and fixing frame 9 (equivalent to the fixing frame) that presses the film moistureproof substrate 7 from the one surface 7b thereof so that the film moistureproof substrate 7 comes in close contact with the reference surface 3, using the adhesive 6.

With this arrangement, the film moistureproof substrate 7 is fixed to the frame body 3 in a state corrected by not only the reference surface 3a but also the pressing and fixing frame 9, thereby correcting the film moistureproof substrate 7 more closely to a shape that conforms with the reference surface 3a.

FIG. 7 is a partial cross-sectional view illustrating an alternative embodiment of the film moistureproof substrate 7 and the fixing frame 9 fixed to the frame body 3 of FIG. 6. The following description of FIG. 7 will focus on the differences between FIG. 6 and embodiment 2.

According to the configuration shown in FIG. 7, the configuration differs from that shown in FIG. 6 in that each end portion of the film moistureproof substrate 7 and the fixing frame 9 are not in contact with the rear surface of the fixing body 3, and the moistureproof adhesive 6 is filled in each end portion of the film moistureproof substrate 7, the fixing frame 9, and the frame body 3. When the moistureproof adhesive 6 is thus filled, the moistureproof capability increases further than in a case where each end portion is sealed as shown in FIG. 6, and the moistureproof adhesive 6 more readily enters each end portion in a sufficient manner, thereby causing the film moistureproof substrate 7 to be more reliably fixed to the frame body 3 by the moistureproof adhesive 6.

### Embodiment 3

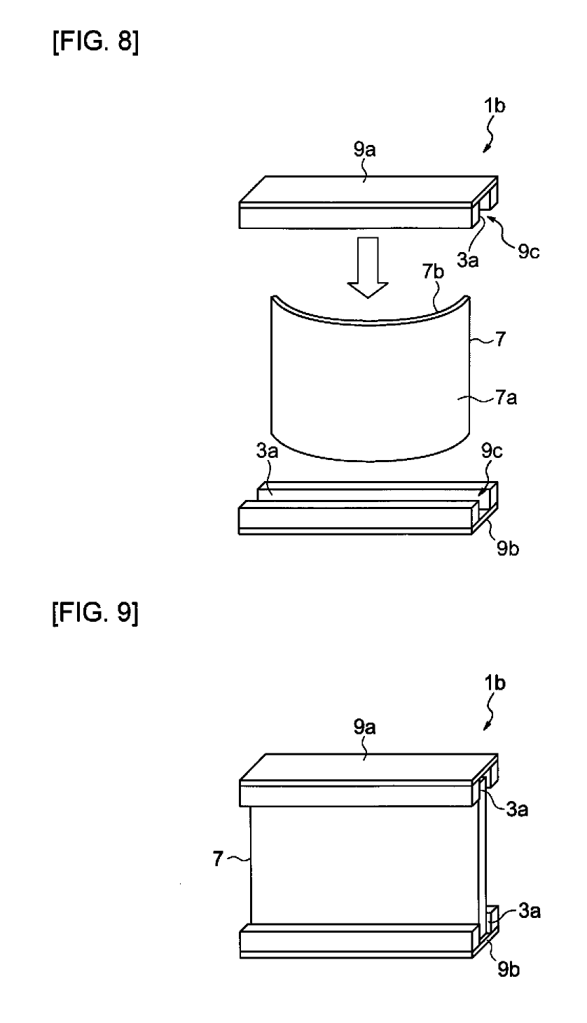

FIG. 8 and FIG. 9 are each a perspective view illustrating an example of the process, in part, used to assemble an organic EL display panel 1b of embodiment 3. Note that FIG. 8 and FIG. 9 are simplified views that focus on the members related to the embodiment.

Note that the components of the organic EL display panel 1b of embodiment 3 that are substantially the same as those of embodiment 1 are denoted using same reference numerals as those of FIGS. 1 to 4 of embodiment 1, and descriptions thereof will be omitted. The following description will focus on the differences between the embodiments.

According to embodiment 3, the film moistureproof substrate 7, distorted as shown in FIG. 8, is sandwiched by a fixing frame 9a as a frame body from above and a fixing frame 9b from below as shown in FIG. 9.

Specifically, these fixing frames 9a and 9b each form a groove 9c, and each of the grooves 9c of the fixing frames 9a and 9b completely sandwich the upper and lower end portions of the film moistureproof substrate 7. The aforementioned reference surface 3a is formed on the inner peripheral surface of this groove 9c. Note that the reference formed on the inner peripheral surface of the groove 9c may be the aforementioned reference point 3d.

Then, the aforementioned moistureproof adhesive 6 is filled in these grooves 9c, and these fixing frames 9a and 9b fix the film moistureproof substrate 7 with the upper and lower end portions of the film moistureproof substrate 7 sandwiched therebetween. When the moistureproof adhesive 6 is thus filled inside the grooves 9c, the upper and lower end portions of the film moistureproof substrate 7 are sealed, making it possible to inhibit the penetration of humidity, moisture, and oxygen therefrom.

In the organic EL display panel 1b of the above embodiment, the frame bodies 9a and 9b each have the groove 9c forming the reference surface 3a, and the moistureproof fixing portion support the end portions of the rectangular film moistureproof substrate 7 on mutually opposing sides pressing the end portions of the film moistureproof substrate 7 so as to perform a close contact with the reference surfaces 3a of the grooves 9c.

With this arrangement, the groove-shaped correcting members 9a and 9b are capable of inhibiting penetration of humidity, moisture, and oxygen from the end portions while the grooves 9c support the end surfaces of the film moistureproof substrate 7.

<Alternative embodiment 1 of embodiment 3>

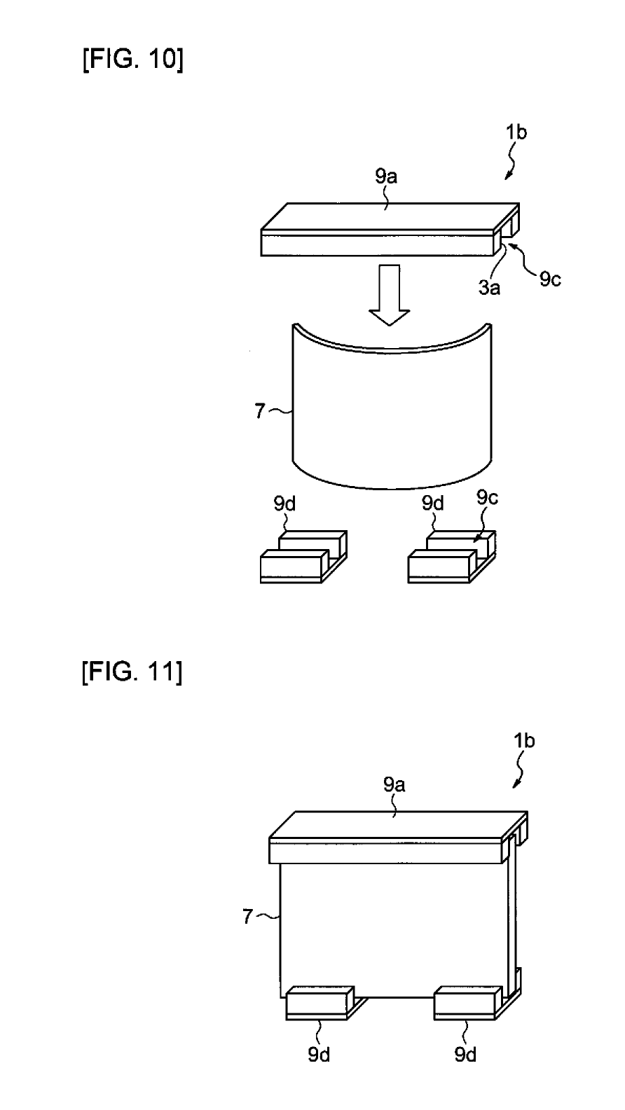

FIG. 10 and FIG. 11 are each a perspective view illustrating an example of the process, in part, used to assemble the organic EL display panel 1b of alternative embodiment 1 of embodiment 3. Note that FIG. 10 and FIG. 11 are simplified views that focus on the members related to the embodiment.

According to the alternative embodiment 1 of embodiment 3, a fixing frame 9d as a frame body is used in place of the aforementioned fixing frame 9b on the lower side. The fixing frame 9a sandwiches the film moistureproof substrate 7 in substantially the same manner as described above, and a description thereof will be omitted. The fixing frame 9d differs from the aforementioned fixing frame 9b by the groove 9c. That is, portions of the end portion of the lower side of the film moistureproof substrate 7 of the embodiment shown in FIG. 10 are sandwiched as illustrated in FIG. 11 to correct the shape.

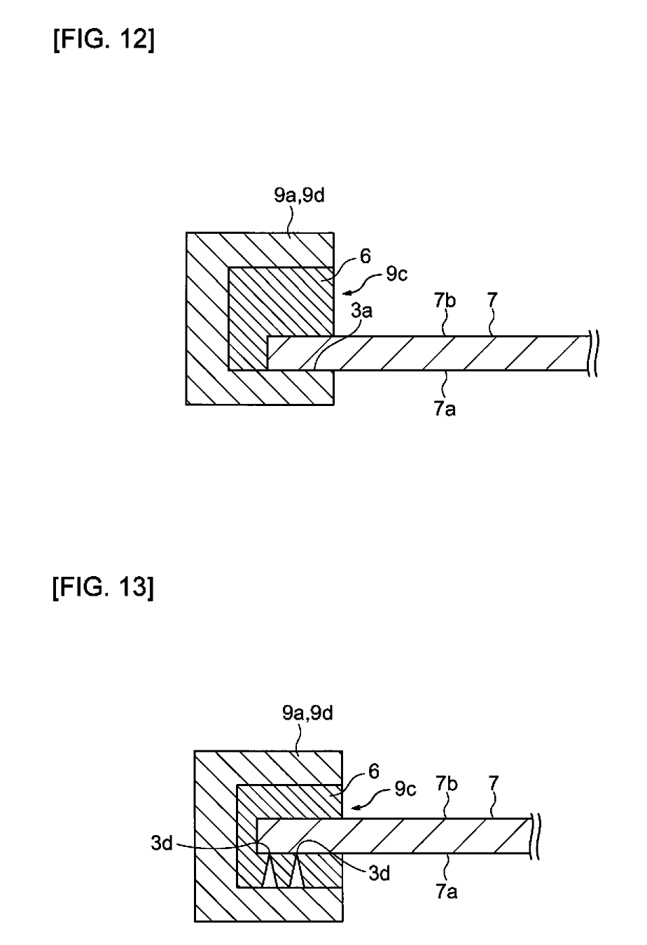

FIG. 12 is a cross-sectional view illustrating a first cross-sectional configuration example of the fixing frames 9a and 9d shown in FIG. 10 and FIG. 11.

As illustrated in FIG. 12, the fixing frames 9a and 9d each form the reference surface 3a within the groove 9c. The reference surface 3a has the function of correcting the shape of the film moistureproof substrate 7 while in close contact with the film moistureproof substrate 7 in substantially the same manner as each of the above embodiments. The aforementioned moistureproof adhesive 6 is filled in the groove 9c, fixing the film moistureproof substrate 7 disposed within the groove 9c and inhibiting the penetration of humidity, moisture, and oxygen from the end portions thereof.

FIG. 13 is a cross-sectional view illustrating a second cross-sectional configuration example of the fixing frames 9a and 9d shown in FIG. 10 and FIG. 11.

As illustrated in FIG. 13, the fixing frame 9a forms the reference points 3d within the groove 9c. The reference points 3d have the function of correcting the shape of the film moistureproof substrate 7 in substantially the same manner as each of the above embodiments. The aforementioned moistureproof adhesive 6 is filled in the groove 9c, fixing the film moistureproof substrate 7 disposed within the groove 9c and inhibiting the penetration of humidity, moisture, and oxygen from the end portions thereof.

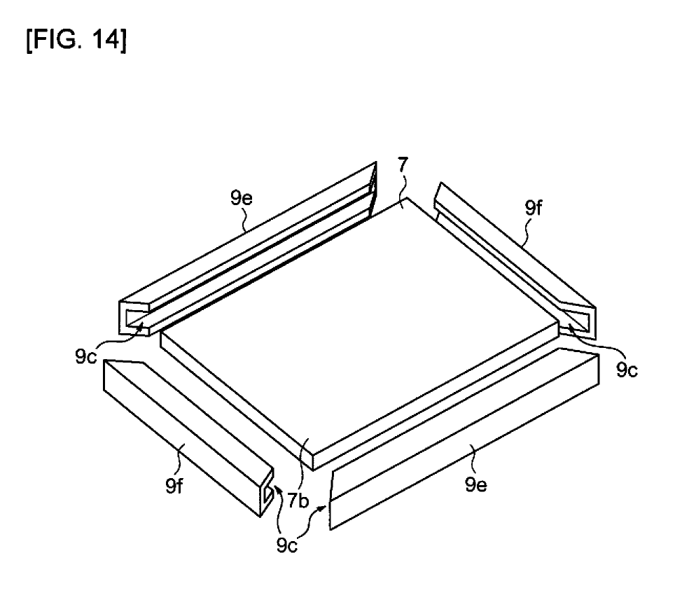

FIG. 14 is a perspective view illustrating an example of fixing the end portions of the film moistureproof substrate 7 using fixing frames 9e and 9f. Note that FIG. 14 is a simplified view that focuses on the members related to the embodiment.

The mutually opposing sides of the four sides of the rectangular film moistureproof substrate 7 are respectively supported by the fixing frames 9e and 9f. The fixing frames 9e and 9f as frame bodies have substantially the same configuration as the aforementioned fixing frames 9a and 9b. According to each of these fixing frames 9e and 9f, the reference surface 3a or the reference point 3d is formed within the groove 9c, and the groove 9c is filled with the moistureproof adhesive 6 with the film moistureproof substrate 7 sandwiched therebetween.

<Alternative embodiment 2 of embodiment 3>

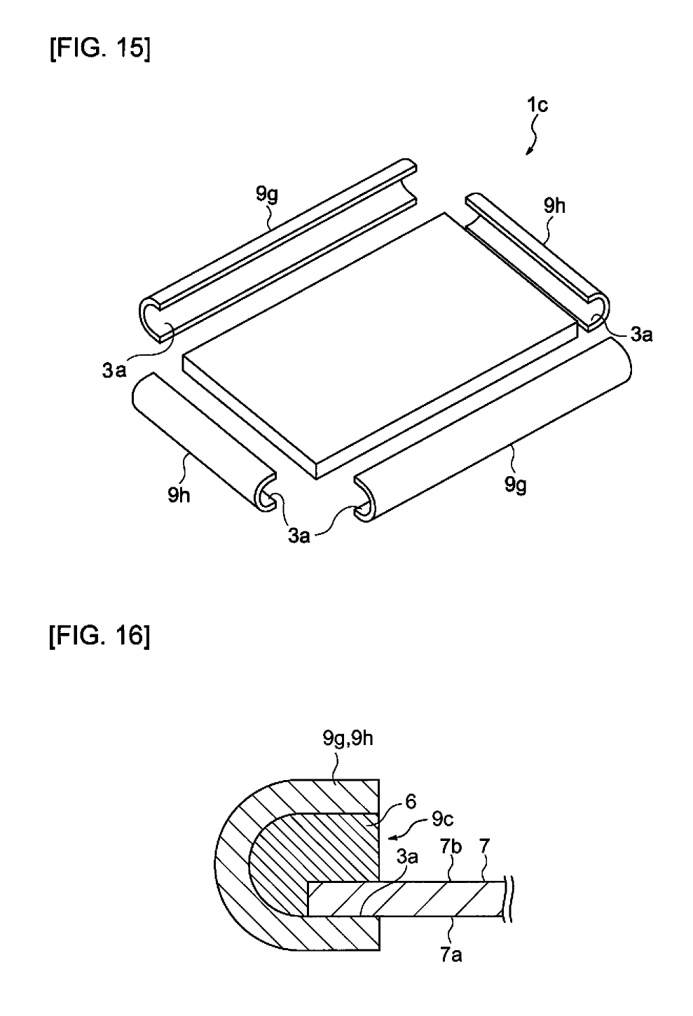

FIG. 15 is a perspective view illustrating an example of the process, in part, used to assemble an organic EL display panel 1c of alternative embodiment 2 of embodiment 3, and FIG. 16 is a cross-sectional view illustrating a configuration example of fixing frames 9g and 9h of FIG. 15. Note that FIG. 15 is a simplified view that focuses on the members related to the embodiment.

In the alternative embodiment 2 of embodiment 3, descriptions of the shapes that are substantially the same as those in the above alternative embodiment 1 of embodiment 3 will be omitted, and the focus will be placed on the differences between the embodiments. According to the alternative embodiment 2 of embodiment 3, the fixing frames 9e and 9f are each changed to a half-cylindrical shape, as illustrated by the frames 9g and 9h.

Specifically, the cross-sectional shapes of the aforementioned fixing frames 9e and 9f are changed into shapes having extended substantially semicircular end portions, forming the fixing frames 9g and 9h as illustrated in FIG. 16. The extended sections form the above-described reference surface 3a, etc. The fixing frames 9g and 9h as frame bodies are materials similar to the above fixing frames 9e and 9f, and similarly exhibit a moistureproof effect.

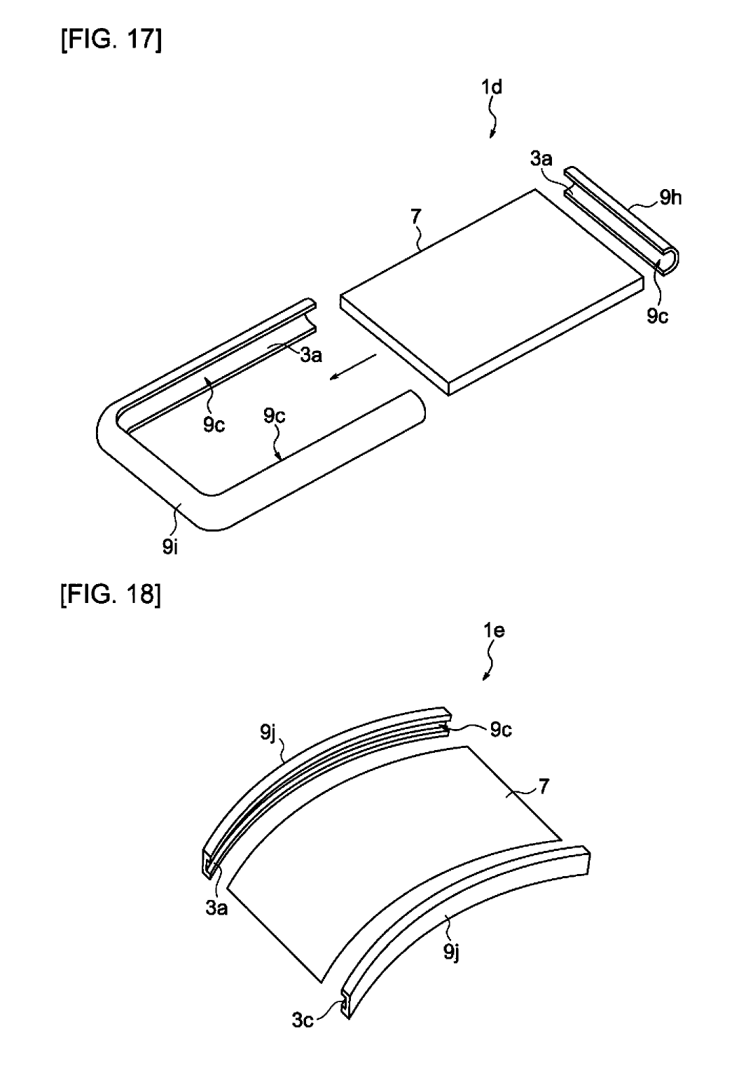

Note that the fixing frames 9g and 9h may be designed so that the fixing frame 9g of two sides and the fixing frame 9h of one side are substantially integrated. Specifically, for example, the film moistureproof substrate 7 may be inserted in the groove 9c of a U-shaped fixing frame 9i as illustrated in FIG. 17. The four sides of the film moistureproof substrate 7 are then sandwiched by the fixing frames 9h and 9i as frame bodies. The reference surface 3a is formed on these fixing frames 9h and 9i. The moistureproof adhesive 6 is filled in the grooves 9c of the fixing frames 9h and 9i with the film moistureproof substrate 7 in close contact with the reference surface 3a, thereby fixing the film moistureproof substrate 7 while correcting it according to the reference surface 3a.

### Embodiment 4

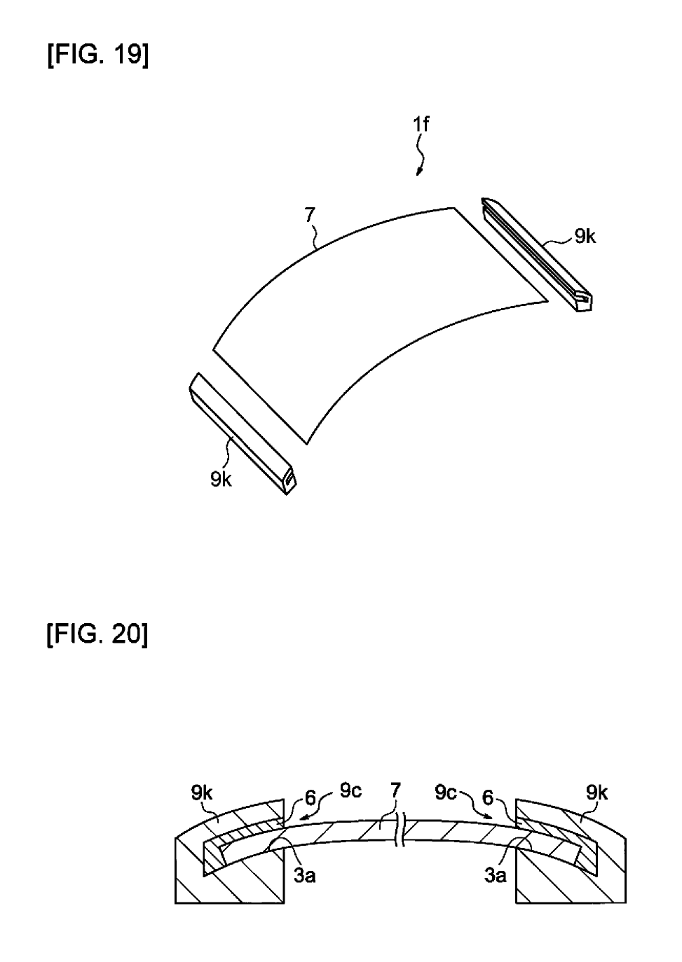

FIG. 18 and FIG. 19 are each a perspective view illustrating an example of the process, in part, used to assemble an organic EL display panel le of embodiment 4. Note that FIG. 18 is a simplified view that focuses on the members related to the embodiment.

Note that the components of the organic EL display panel 1e of embodiment 4 that are substantially the same as those of embodiments 1 to 3 are denoted using same reference numerals as those in FIG. 1 to FIG. 17 of embodiment 1, and descriptions thereof will be omitted. The following description will focus on the differences between the embodiments.

While embodiments 1 to 3 each described an illustrative scenario in which the film moistureproof substrate 7 is corrected to a flat surface, embodiment 4 describes an illustrative scenario in which the film moistureproof substrate 7 is corrected to a curved surface of a desired curvature.

Specifically, a fixing frame 9j as a frame body comprises a groove 9c that forms a desired curve, as illustrated in FIG. 18. The cross-sectional shape of this groove 9c is substantially the same as that in the above embodiments 1 to 3, and a description thereof will be omitted. The fixing frame 9j has a configuration that makes it possible to sandwich an end portion of the film moistureproof substrate 7 in the longitudinal direction by the groove 9c. When the film moistureproof substrate 7 is thus sandwiched by the groove 9c, the fixing frame 9j corrects the film moistureproof substrate 7 so that it forms a predetermined curved surface along the reference surface 3a of the groove 9c.

FIG. 19 is a perspective view illustrating an example of the process, in part, used to assemble an organic EL display panel if of an alternative embodiment of embodiment 4, and FIG. 20 is a cross-sectional view illustrating a cross-sectional configuration example of a fixing frame 9k of FIG. 19. Note that FIG. 19 and FIG. 20 are simplified views that focus on the members related to the embodiment.

The sandwiched sections of the film moistureproof substrate 7 are not limited to the end portions along the longitudinal direction such as illustrated in FIG. 18, allowing use of the end portions along the shorter direction that is substantially perpendicular to the longitudinal direction, as illustrated in FIG. 19. Specifically, a plurality of the fixing frames 9k as frame bodies that form the groove 9c similar to the fixing frame 9j may sandwich the end portions of two sides along the shorter direction.

At this time, with the reference surface 3a of the groove 9c in close contact with and supporting the film moistureproof substrate 7, thereby correcting the film moistureproof substrate 7 to a desired curved surface as illustrated in FIG. 20, the film moistureproof substrate 7 is fixed to the fixing frames 9k by the moistureproof adhesive 6. With this arrangement, the end portions of the film moistureproof substrate 7 are sealed by the moistureproof adhesive 6 to inhibit penetration of humidity, moisture, and oxygen. In addition, according to the configuration shown in FIG. 20, it is possible to match the curvature of the film moistureproof substrate 7 with the curvature of the reference surface 3a of the fixing frame 9k.

### Embodiment 5

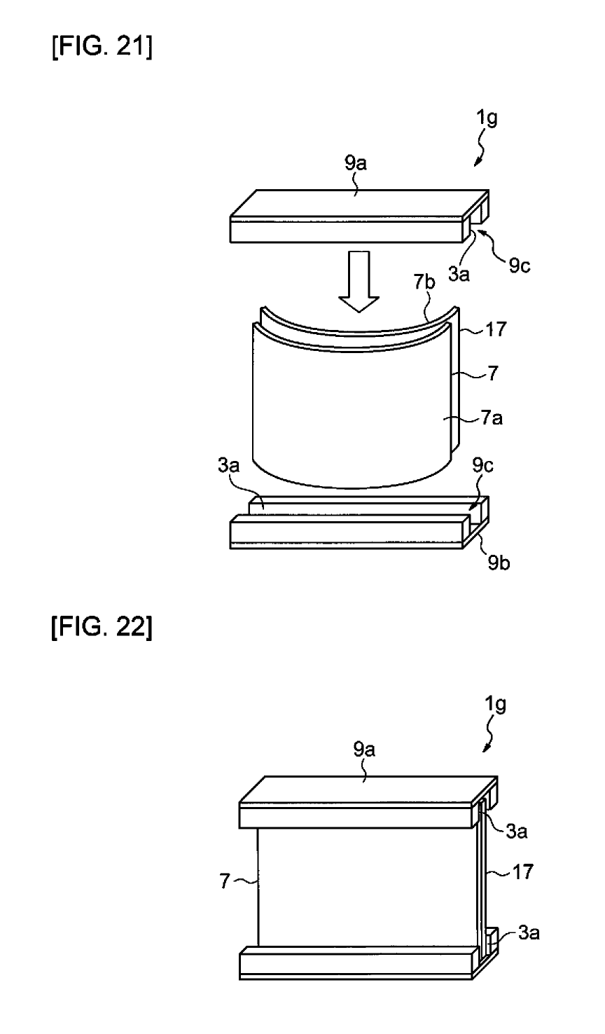

FIG. 21 and FIG. 22 are each a perspective view illustrating an example of the process, in part, used to assemble an organic EL display panel 1g of embodiment 5. Note that FIG. 21 and FIG. 22 are simplified views that focus on the members related to the embodiment.

Note that the components of the organic EL display panel 1g of embodiment 5 that are substantially the same as those of embodiment 3 are denoted using same reference numerals as those in FIG. 1 to FIG. 13 of embodiment 3, and descriptions thereof will be omitted. The following description will focus on the differences between the embodiments.

While embodiment 3 has one film moistureproof substrate 7 (single substrate), embodiment 5 differs from embodiment 3 in that it has two film moistureproof substrates 7 and 17. Note that the film moistureproof substrate 7 of embodiment 5 has substantially the same configuration as that of the film moistureproof substrate 7 of the above embodiment 3. In addition, the film moistureproof substrates 7 and 17 may be pasted together, or may be a plurality of substrates that are not pasted together.

The film moistureproof substrate 17 is a substrate that is equivalent to the other film moistureproof substrate, having, for example, a moistureproof action, and comprises a function of protecting the film moistureproof substrate 7 from humidity, moisture, and oxygen. This film moistureproof substrate 17 thus exhibits moistureproof characteristics, but does not have the aforementioned thin-film organic electroluminescent elements, unlike the film moistureproof substrate 7. In the case of an organic EL, the sealing plate of the fixing and sealing process corresponds to 17.

The film moistureproof substrate 17 is provided along the front surface of the film moistureproof substrate 7. With the film moistureproof substrate 7 and the film moistureproof substrate 17 thus superimposed, the upper and lower end portions thereof are supported by the fixing frames 9a and 9b as frame bodies, respectively. At this time, the upper and lower end portions are corrected by the reference surface 3a provided to both the fixing frames 9a and 9b and, as a result, the film moistureproof substrate 7 and the film moistureproof substrate 17 are corrected to a desired shape.

Examples of the material used for the moistureproof film of the film moistureproof substrate 7 and the film moistureproof substrate 17 mainly include inorganic silicon films, such as SiON, SiO₂, SiN, and SiOC. The moistureproof film formation method used may be a vacuum thin film coating method, such as spattering or CVD, for example. According to this embodiment 5, a substrate having a moistureproof function is formed by forming a moistureproof film on a film substrate. According to such a configuration, it is possible to inhibit the penetration of moisture and oxygen from both the front and rear surfaces of the formed substrate. Note that the aforementioned surface 3a contacts this moistureproof film.

In addition, the film moistureproof substrate 7 and the film moistureproof substrate 17 may be bonded together using an adhesive, for example. Examples of the adhesive used include an acrylic or epoxy that is based on thermal or UV (ultraviolet light) curing, similar to that used when adhering the fixing plates 9a and 9b, for example. While this embodiment describes an illustrative scenario in which a plurality of substrates (the film moistureproof substrate 7 and the film moistureproof substrate 17) is employed, a process technique referred to as solid sealing may be mainly used to seal the substrates and sealing plates in organic EL display panel applications.

The organic EL display panel 1g of the above embodiment, in addition to the above configuration, further comprises another film moistureproof substrate 17 provided along the front surface of the film moistureproof substrate 7, wherein the moistureproof fixing portion fixes the other film moistureproof substrate 17 the film moistureproof substrate 7 to the frame bodies 9a, 9b in a state that the other film moistureproof substrate 17 and the film moistureproof substrate 7 are superimposed.

With this arrangement, since the film moistureproof substrate 17 is provided on the front surface of the film moistureproof substrate 7, the film moistureproof substrate 7 is capable of inhibiting the penetration of humidity, moisture, and oxygen from the end portions as well as the front surface of the film moistureproof substrate 7. In addition, the film moistureproof substrate 7 is corrected in accordance with the reference surface 3a along with the other film moistureproof substrate 17.

<Alternative embodiment of embodiment 5>

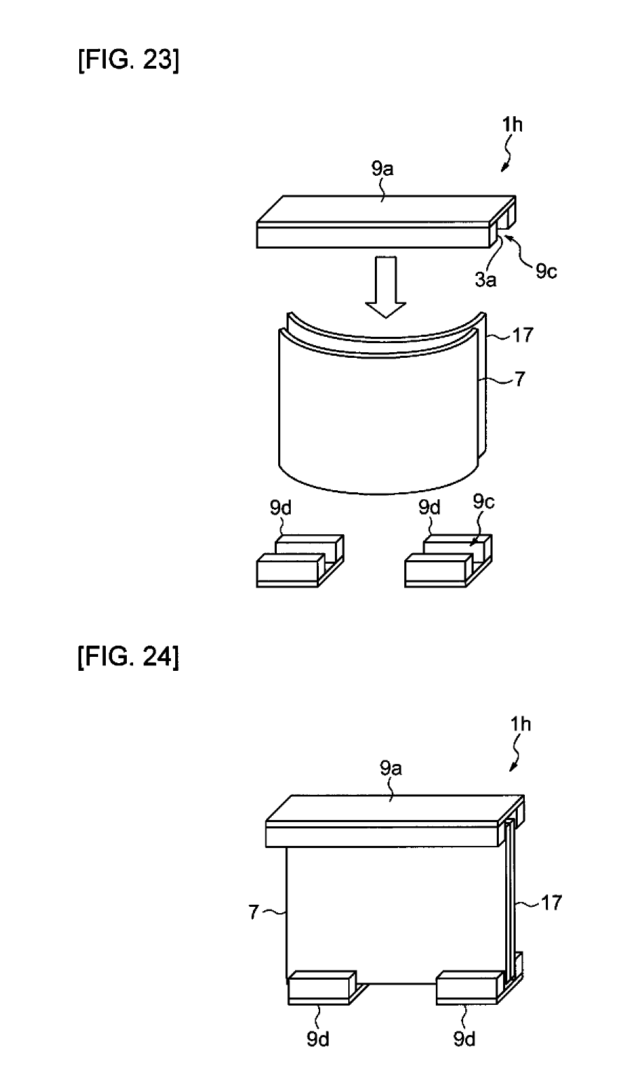

FIG. 23 and FIG. 24 are each a perspective view illustrating an example of the process, in part, used to assemble an organic EL display panel 1h of an alternative embodiment of embodiment 5. Note that FIG. 23 and FIG. 24 are simplified views that focus on the members related to the embodiment.

According to the alternative embodiment of embodiment 5, the fixing frames 9d as a frame body are used in place of the aforementioned fixing frame 9b on the lower side. The fixing frame 9a sandwiches the film moistureproof substrate 7 in substantially the same manner as described above, and a description thereof will be omitted. This fixing frames 9d differ from the aforementioned fixing frames 9b by the groove 9c. That is, portions of the lower end portion of the film moistureproof substrate 7 of the embodiment shown in FIG. 23 are sandwiched as illustrated in FIG. 24.

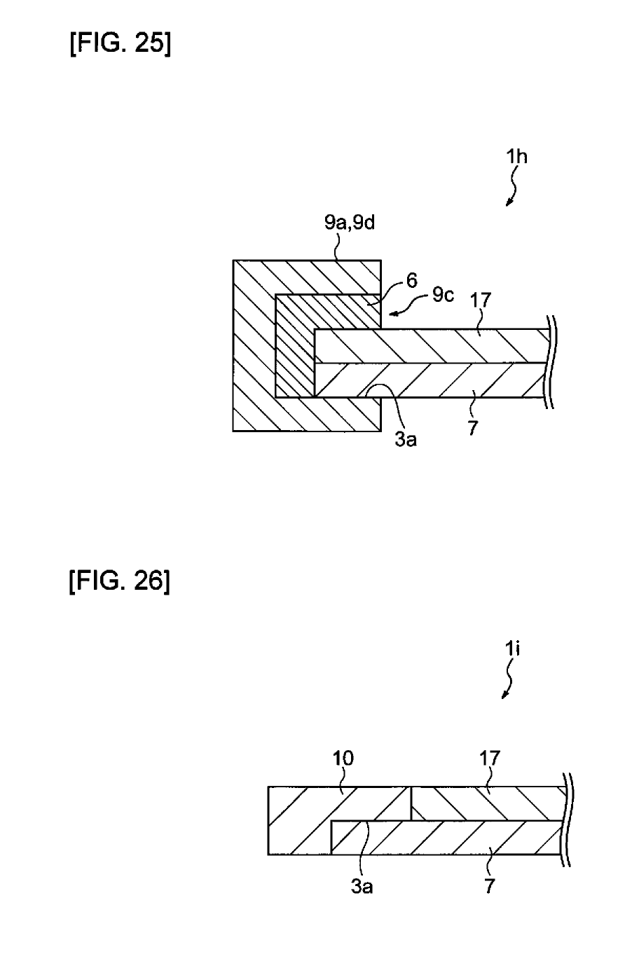

FIG. 25 is a cross-sectional view illustrating a cross-sectional configuration example of the fixing frames 9a and 9d shown in FIG. 23 and FIG. 24.

As illustrated in FIG. 25, the fixing frames 9a and 9d each form the reference surface 3a within the groove 9c. The reference surface 3a has the function of correcting the shape of the film moistureproof substrate 7 in substantially the same manner as each of the above embodiments. The aforementioned moistureproof adhesive 6 is filled in the groove 9c, fixing the film moistureproof substrate 7 disposed within the groove 9c and inhibiting the penetration of humidity, moisture, and oxygen from the end portions thereof.

With this arrangement, the film moistureproof substrate 7 is fixed to the fixing frames 9a and 9d along with the film moistureproof substrate 17 while in close contact with the reference surface 3a, using the moistureproof adhesive 6. This makes it possible to prevent the film moistureproof substrate 17 from separating from the film moistureproof substrate 7.

Note that the embodiments of the present invention are not limited to the above, and various modifications are possible. In the following, details of such modifications will be described one by one.

### Alternative Embodiment 1

FIG. 26 is a cross-sectional view illustrating a configuration example of a portion of an organic EL display panel 1i of alternative embodiment 1 of the fifth embodiment. Note that in alternative embodiment 1 a description will be omitted for those components that are substantially the same as those of each of the above-described embodiments, and the focus will be placed on the differences from each of the above fifth embodiment.

According to alternative embodiment 1, the film moistureproof 7 is fixed to a fixing frame 10 (equivalent to a frame body, a fixing member body) while superimposed on the film moistureproof substrate 17, similar to the above embodiment 5. The combined thickness of the film moistureproof substrate 7 and the film moistureproof substrate 17 is substantially the same as the thickness of the fixing frame 10. A slight difference in surface area exists between the film moistureproof substrate 7 and the film-moisture proof substrate 17. The section formed by this surface area difference is in close contact with a coherence surface 3a (equivalent to a moistureproof fixing portion) of the fixing frame 10. The coherence surface 3a also functions as the reference surface 3a that is substantially the same as in each of the above embodiments.

According to the alternative embodiment 1, the surface area of the film moistureproof substrate 17 is smaller than the surface area of the film moistureproof substrate 7, and the surface of a portion of the film moistureproof substrate 7 is in close contact with the coherence surface 3a of the fixing frame 10. The fixing frame 10 has a moistureproof function that inhibits humidity and moisture and an oxygen permeation control function. The coherence surface 3a, similar to each of the above embodiments, has the function of correcting the film moistureproof substrate 7 so that it forms a desired shape.

In addition, this fixing frame 10 is mainly disposed on the side of the film moistureproof substrate 7 and the film moistureproof substrate 17 to cover the end potions thereof, thereby inhibiting the penetration of humidity, moisture, and oxygen from the end portions.

In the organic EL display panel 1i of the alternative embodiment 1, in addition to the above configuration, the frame body includes the fixing member body 10 (equivalent to the fixing frame) that fixes the film moistureproof substrate 7 and the other film moistureproof substrate 17 in a superimposed state, and the moistureproof fixing portion comprises the coherence surface 3a that is in close contact the section of the bonded film moistureproof substrate 7 and the film moistureproof substrate 17 where there is a difference in surface area, and functions as the reference surface.

With this arrangement, the coherence surface 3a of the fixing member body 10 is capable of correcting the film moistureproof substrate 7 and the other film moistureproof substrate 17 to a desired shape, and the fixing member body 10 is capable of exhibiting a moistureproof effect that inhibits the penetration of humidity and moisture from each end portion of the film moistureproof substrate 7 and the other film moistureproof substrate 17 as well as decreasing the size in the thickness direction.

The organic EL display panel 1i of the above embodiment comprises a configuration wherein, in addition to the above configuration, the thickness of the fixing member body 10 is substantially equal to the combined thickness of the superimposed film moistureproof substrate 7 and the other film moistureproof substrate 17.

With this arrangement, the thickness of the fixing member body 10 is equal to the thickness of the film moistureproof substrate 7 and the other film moistureproof substrate 17, thereby making it possible to flatten the area from the fixing member body 10 to the front surface of the film moistureproof substrate 7 or the other film moistureproof substrate 17. This makes it possible to achieve the thinness demanded in a film EL.

### Alternative Embodiment 2

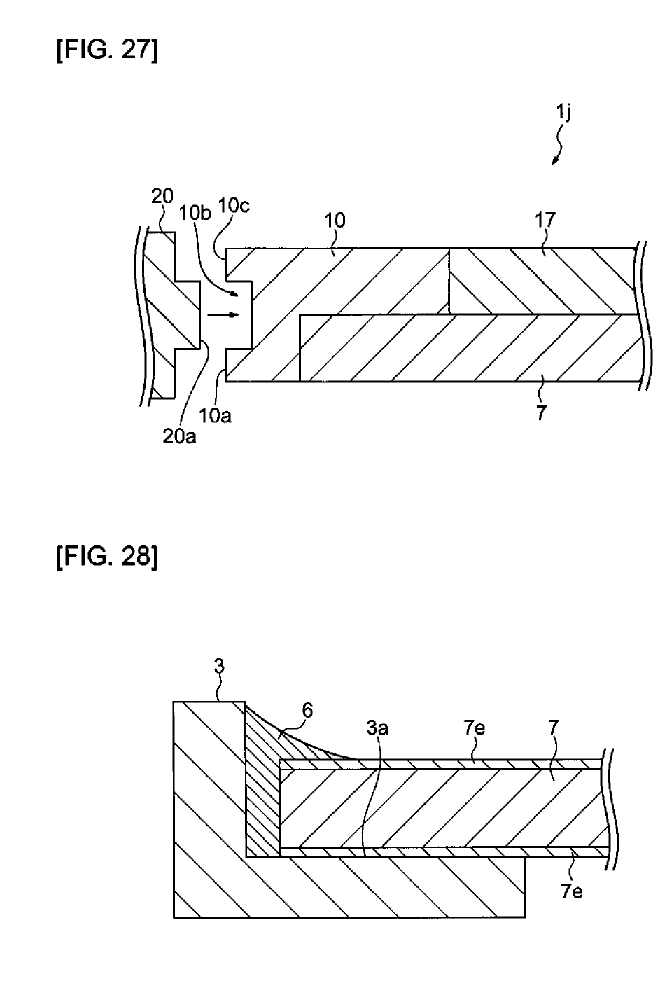

FIG. 27 is a cross-sectional view illustrating a configuration example of a portion of an organic EL display panel 1j of alternative embodiment 2, which is a further modification of the alternative embodiment 1.

In alternative embodiment 2, the configuration is substantially the same as that of alternative embodiment 1, but the shape of the fixing member body 10 differs as follows.

A second joining portion 10b of a groove shape is formed on a side surface 10c of the fixing member body 10 of the above alternative embodiment 1. On the other hand, a first joining portion 20a of a convex shape is formed on a display device body 20 that emits light from the film moistureproof substrate 7 to display a desired image. This first joining portion 20a is designed to mate with the second joining portion 10b. When the first joining portion 20a is thus mated with the second joining portion 10b, the film moistureproof substrate 7 and the film moistureproof substrate 17 are fixed to the fixing frame body 10 and the display device body 20.

The moisture permeability of the fixing member body 10 is, for example, greater than or equal to 0.01 [g/m² per day] and less than or equal to 100 [g/m² per day]. In addition, the material used for the fixing member body 10 is, for example, a moistureproof insulating material made by Hitachi Chemical to protect the end portions of the film moistureproof substrate 7 and the like. Note that this moistureproof insulating material is often employed as a material for a flat panel display, for example. In the fixing member body 10, the second joining portion 10b is bonded to the first joining portion 20a using the adhesive 6 that is of an ultraviolet curing or thermal curing type, for example.

In the organic EL display panel 1j of the above alternative embodiment, in addition to the above configuration, the second joining portion 10b that mates with the first joining portion 20a of the display device body 20 that emits light from the film moistureproof substrate 7 to display a desired image is formed on the fixing member 10.

With this arrangement, the first joining portion 20a and the second joining portion 10b join together and correct the film moistureproof substrate 7 in such a manner that the reference surface 3a minimizes the deformation thereof in the event the organic EL display panel 1j is subjected to impact when mounted on the display device body 20 causing deformation of the film moistureproof substrate 7.

The organic EL display panel 1j of the above alternative embodiment comprises a configuration wherein, in addition to the above configuration, the coefficients of linear expansion of the film moistureproof substrate 7, the other film moistureproof substrate 17, and the fixing member body 10 are substantially equal.

With this arrangement, the fixing member body 10 shapes the film moistureproof substrate 7 and the other film moistureproof substrate 17 in substantially the same manner, even if the film moistureproof substrate 7 and the other film moistureproof substrate 17 have deformed over time, thereby making the film moistureproof substrate 7, the other film moistureproof substrate 17, and the fixing member body 10 expand substantially in the same manner if moisture is absorbed. As a result, the organic EL display panel 1j is capable of minimizing the effect caused by a difference in expansion due to deformation over time of the film moistureproof substrate 7, the other film moistureproof substrate 17, and the fixing member body 10.

In the organic EL display panel 1j of the above alternative embodiment, in addition to the above configuration, the moisture permeability of the fixing member body 10 is greater than or equal to 0.01 [g/m² per day] and less than or equal to 100 [g/m² per day], for example.

With this arrangement, a moistureproof effect of the end portions of the film moistureproof substrate 7 is sufficiently exhibited, making it possible to improve the reliability of the organic EL display panel 1j.

The organic EL display panel 1 to 1h of each of the above embodiments, in addition to the above configuration, may further comprise the fixing member body 10 that fixes a side of the film moistureproof substrate 7. That is, the above fixing member body 10 may fix the film moistureproof substrate 7 that is not provided with such the film moistureproof substrate 17, from the side.

In the organic EL display panel 1 to 1h of each of the above embodiments, in addition to the above configuration, the second joining portion 10b that mates with the first joining portion 20a of the display device body 20 that emits light from the film moistureproof substrate 7 to display a desired image is formed on the fixing member body 10.

With this arrangement, the first joining portion 20a and the second joining portion 10b join together and correct the film moistureproof substrate 7 in such a manner that the reference surface 3a minimizes the deformation thereof in the event the organic EL display panels 1 to 1h are subjected to impact when mounted on the display device body 20 causing deformation of the film moistureproof substrate 7.

The organic EL display panels 1 to 1h of each of the above embodiments comprises a configuration wherein, in addition to the above configuration, the linear coefficients of expansion of the film moistureproof substrate 7 and the fixing member body 10 are substantially equal.

With this arrangement, the fixing member body 10 changes shape in substantially the same manner as the film moistureproof substrate 7, even if the film moistureproof substrate 7 has deformed over time, causing the film moistureproof substrate 7 and the fixing member body 10 to expand substantially in the same manner if moisture is absorbed. As a result, the organic EL display panels 1 to 1h are each capable of minimizing the effect caused by the difference in expansion due to deformation over time of the film moistureproof substrate 7 and the fixing member body 10.

In the organic EL display panels 1 to 1h of each of the above embodiments, in addition to the above configuration, the moisture permeability of the fixing member body 10 is greater than or equal to 0.01 [g/m² per day] and less than or equal to 100 [g/m² per day], for example.

With this arrangement, a moistureproof effect of the end portions of the film moistureproof substrate 7 is sufficiently exhibited, making it possible to improve the reliability of each of the organic EL display panels 1 to 1h.

FIG. 28 is a partial cross-sectional view illustrating an alternative embodiment of the film moistureproof substrate 7 of FIG. 3. In FIG. 28, the components are substantially the same as those of FIG. 3 of embodiment 1. Descriptions of identical components will therefore be omitted, and the focus will be placed on the differences between the embodiments.

On both surfaces of the film moistureproof substrate 7, a moistureproof film 7e is provided as an example of the other film moistureproof substrate. This moistureproof film 7e is an inorganic film, for example, and has a moistureproof function similar to that of the aforementioned film moistureproof substrate 17. The moistureproof films 7e of both surfaces are formed on both surfaces of the film moistureproof substrate 7. The film moistureproof substrate 7 is fixed to the frame body 3 using the moistureproof adhesive 6, with the moistureproof film 7e in contact with the reference surface 3a. With this arrangement, it is possible to prevent separation of the moistureproof film 7e.

In the organic EL display panel 1j, etc., of the above embodiments and alternative embodiments, in addition to the aforementioned configurations, the other film moistureproof substrate may serve as the moistureproof film 7e formed on the front and rear surfaces of the film moistureproof substrate 7.

With this arrangement, the film moistureproof substrate 7 is capable of exhibiting a moistureproof effect that inhibits penetration of humidity and moisture from the end portions thereof, as well as exhibiting a moistureproof effect that inhibits penetration of humidity and moisture from the front and rear surfaces thereof.

Each of the above embodiments and alternative embodiments may be applied, for example, to film devices, in general. Such general applicable film devices include, for example, organic electroluminescent displays, organic transistors, organic solar cells, semiconductor lasers, and CNT-FET transistors.

1-59. (canceled)

60. A communication system comprising:
a base station having
a resource allocator that defines M unit resources (M is an integer equal to or greater than two) in a first control channel through which first control information is transmitted as a basic resource, associates a resource in a second control channel through which second control information is transmitted with said basic resource, allocates at least part of said basic resource to said first control information, and associates the first control information to which at least part of said basic resource is allocated with a resource in the second control channel associated with one of the basic resources allocated to said first control information, and
a first control information transmitter that transmits said allocated first control information to a mobile station; and
a mobile station having
a second control information transmitter that receives said first control information, and transmits said second control information using the resource in the second control channel associated with said first control information.

61. A communication system according to claim 60, wherein said first control channel is a PDCCH (Physical Downlink Control Channel), the unit resource in said first control channel is a CCE (Control Channel Element), said first control information is a Downlink grant, said second control channel is a PUCCH (Physical Uplink Control Channel), and said second control information is an ACK (Acknowledgement) or NACK (Negative Acknowledgement).

62. A communication system according to claim 60, wherein said resource allocator defines a maximum one of the numbers of unit resources for use in transmitting the first control information as M.

63. A communication system according to claim 60, wherein said resource allocator preferentially allocates a mobile station that transmits the second control information using the second control channel, to the first control channel.

64. A communication system according to claim 60, wherein said resource allocator preferentially allocates a mobile station for which the number of unit resources for use in transmitting said first control information is M among those receiving the first control information, to the first control channel.

65. A communication system according to claim 60, wherein said resource allocator allocates a unit resource in the first control channel that is not used in transmitting said first control information, to a mobile station that does not use a resource in said second control channel associated with said first control information.

66. A communication system according to claim 60, wherein said resource allocator allocates a resource in the second control channel that is not associated with said first control information, to a mobile station that does not use a resource in said second control channel associated with said first control information.

67. A communication system according to claim 60, wherein:
said base station and said mobile station have association relationship information on the association relationship between identification information for said basic resource or unit resources constituting said basic resource and identification information for a resource in said second control channel;
the resource allocator in said base station associates said first control information with a resource in said second control channel based on said association relationship information; and
the second control information transmitter in said mobile station decides a resource in the second control channel associated with received first control information based on the identification information for the basic resource or unit resources constituting said basic resource used in transmitting said received first control information, and said association relationship information.

68. A base station comprising:
a resource allocator that defines M unit resources (M is an integer equal to or greater than two) in a first control channel through which first control information is transmitted as a basic resource, associates a resource in a second control channel through which second control information is transmitted with said basic resource, allocates at least part of said basic resource to said first control information, and associates the first control information to which at least part of said basic resource is allocated with a resource in the second control channel associated with one of the basic resources allocated to said first control information; and
a first control information transmitter that transmits said allocated first control information to said mobile station.

69. A base station according to claim 68, wherein said first control channel is a PDCCH (Physical Downlink Control Channel), the unit resource in said first control channel is a CCE (Control Channel Element), said first control information is a Downlink grant, said second control channel is a PUCCH (Physical Uplink Control Channel), and said second control information is an ACK (Acknowledgement) or NACK (Negative Acknowledgement).

70. A base station according to claim 68, wherein said resource allocator defines a maximum one of the numbers of unit resources for use in transmitting the first control information as M.

71. A base station according to claim 68, wherein said resource allocator preferentially allocates a mobile station that transmits the second control information using the second control channel, to the first control channel.

72. A base station according to claim 68, wherein said resource allocator preferentially allocates a mobile station for which the number of unit resources for use in transmitting said first control information is M among those receiving the first control information, to the first control channel.

73. A base station according to claim 68, wherein said resource allocator allocates a unit resource in the first control channel that is not used in transmitting said first control information, to a mobile station that does not use a resource in said second control channel associated with said first control information.

74. A base station according to claim 68, wherein said resource allocator allocates a resource in the second control channel that is not associated with said first control information, to a mobile station that does not use a resource in said second control channel associated with said first control information.

75. A base station according to claim 68, wherein:
said base station has association relationship information on the association relationship between identification information for said basic resource or unit resources constituting said basic resource, and identification information for a resource in said second control channel; and
said resource allocator associates said first control information with a resource in said second control channel based on said association relationship information.

76. A mobile station for receiving first control information, for which M unit resources (M is an integer equal to or greater than two) in a first control channel through which the first control information is transmitted from a base station are defined as a basic resource, and in which a resource in a second control channel through which second control information is transmitted is associated with said basic resource, said first control information being transmitted using at least part of said basic resource, and transmitting second control information using a resource in the second control channel associated with received first control information, said mobile station comprising:
association relationship information that is information on the association relationship between said basic resource or unit resources constituting said basic resource and a resource in the second control channel through which the second control information is transmitted; and
a control information transmitter that decides a resource in the second control channel associated with said received first control information based on the information for the basic resource for said received first control information or unit resources constituting said basic resource, and said association relationship information.

77. A mobile station according to claim 76, wherein said first control channel is a PDCCH (Physical Downlink Control Channel), the unit resource in said first control channel is a CCE (Control Channel Element), said first control information is a Downlink grant, said second control channel is a PUCCH (Physical Uplink Control Channel), and said second control information is an ACK (Acknowledgement) or NACK (Negative Acknowledgement).

78. A mobile station according to claim 76, wherein said M is a maximum one of the numbers of unit resources for use in transmitting the first control information.

79. A communication method wherein:
a first wireless station transmits first control information to a second wireless station using at least one unit resource in a first control channel; and
a second wireless station transmits second control information using a resource in a second control channel associated with a resource consisting of M unit resources (M is an integer equal to or greater than two) in said first control channel.

80. A communication method according to claim 79, wherein said first control channel is a PDCCH (Physical Downlink Control Channel), the unit resource in said first control channel is a CCE (Control Channel Element), said first control information is a Downlink grant, said second control channel is a PUCCH (Physical Uplink Control Channel), and said second control information is an ACK (Acknowledgement) or NACK (Negative Acknowledgement).

81. A communication method according to claim 79, wherein said M is a maximum one of the numbers of unit resources for use in transmitting the first control information.
